(19) United States
(12) Patent Application Publication
(10) Pub. No.: US 2025/0366274 A1
(43) Pub. Date: Nov. 27, 2025

(54) LIGHT EMITTING DIODE PACKAGE AND LIGHT EMITTING DIODE LAMP BEAD

(71) Applicant: Shenzhen Refond Optoelectronics Co., Ltd, Shenzhen (CN)

(72) Inventors: Ji Wu, Shenzhen (CN); Longxiang Lin, Shenzhen (CN); Juan Liu, Shenzhen (CN); Weibin Gong, Shenzhen (CN)

(21) Appl. No.: 19/218,240

(22) Filed: May 24, 2025

(30) Foreign Application Priority Data
May 24, 2024 (CN) 202421165851.7

(51) Int. Cl. H10H 20/853; H10H 20/851; H10H 20/856

(52) U.S. Cl. CPC H10H 20/853; H10H 20/851; H10H 20/856

(57) ABSTRACT

The present disclosure relates to the technical field of light emitting diode (LED) packaging, and in particular to an LED package and an LED lamp bead. The LED package includes a reflector cup bracket hollow to form a housing space. A first adhesive layer, a second adhesive layer, and a color conversion layer arranged between the first adhesive layer and the second adhesive layer are arranged in the housing space. When the LED package is packaged with an LED chip, the color conversion layer can be directly used for cutting, and the LED package can be directly attached above the LED chip for color conversion, which not only ensures the color consistency of a device, but also avoids the failure of a film material contacting with water vapor, thereby saving the cost of the entire film material.

### CROSS-REFERENCE TO RELATED APPLICATION

This application claims priority of Chinese Patent Application No. 202421165851.7, filed on May 24, 2024, the entire contents of which are incorporated herein by reference.

### TECHNICAL FIELD

The present disclosure relates to the technical field of light emitting diode (LED) packaging, and in particular to an LED package and an LED lamp bead.

### BACKGROUND

With the increasing demand of consumers for high-resolution and low-energy displays, MiniLED backlight technology is also developing.

The white light solution of existing MiniLED backlight technology usually packages blue chip-on-board (COB) and a color conversion film to obtain white light, but the cost of color conversion by using blue COB is high.

### SUMMARY

To overcome the problem that the cost of color conversion by using blue COB in the existing MiniLED backlight technology is high, the present disclosure provides an LED package and an LED lamp bead.

A solution of the present disclosure to solve the technical problem is to provide an LED package, including an LED package, a reflector cup bracket hollow to form a housing space. A first adhesive layer, a second adhesive layer, and a color conversion layer arranged between the first adhesive layer and the second adhesive layer are arranged in the housing space, and a surface of the second adhesive layer away from the color conversion layer is recessed toward the color conversion layer to form a recessed space.

Preferably, an inner wall of the reflector cup bracket is arranged with a step, and a surface of the color conversion layer facing the second adhesive layer is abutted against the step.

Preferably, the LED package of the present disclosure further includes an optical structure, and the optical structure is arranged on a surface of the first adhesive layer away from the color conversion layer.

Preferably, the optical structure is one of a light reflecting layer, a light shielding layer, a third adhesive layer and a lens layer.

Preferably, the light reflecting layer or the light shielding layer is arranged in a middle region of a surface of the first adhesive layer away from the color conversion layer.

Preferably, the third adhesive layer covers the first adhesive layer and protrudes in a direction away from the first adhesive layer.

Preferably, the lens layer is arranged in the middle region of the surface of the first adhesive layer away from the color conversion layer.

Preferably, thicknesses of the first adhesive layer and the second adhesive layer are greater than 0 mm and less than or equal to 10 mm.

Preferably, a distance between a recessed vertex of the recessed space and a bottom surface of the housing space is greater than 0 mm and less than or equal to 5 mm.

The present disclosure further provides an LED lamp bead, including a substrate, an LED chip arranged on the substrate, and the LED package as described above. A packaging adhesive layer is arranged on the LED chip, the LED chip is located in the recessed space, and the packaging adhesive layer is connected to the second adhesive layer.

Compared with the related art, the LED package and the LED lamp bead of the present disclosure have the following advantages.
1. In the present disclosure, the LED package is provided, including a reflector cup bracket hollow to form a housing space. A first adhesive layer, a second adhesive layer, and a color conversion layer arranged between the first adhesive layer and the second adhesive layer are arranged in the housing space, and a surface of the second adhesive layer away from the color conversion layer is recessed toward the color conversion layer to form a recessed space. By arranging the first adhesive layer, the second adhesive layer and the color conversion layer in the housing space of the reflector cup bracket, the LED package independent of the LED chip can be formed, and the arranged recessed space is a reserved space for placing the LED chip. Therefore, when the LED package and the LED chip are packaged, the color conversion layer can be directly used for cutting, and the LED package can be directly attached above the LED chip for color conversion, which not only ensures the color consistency of the device, but also avoids the failure of a film material contacting with water vapor, thereby saving the cost of the entire film material, and further greatly reducing the cost of color conversion.
2. In the present disclosure, an inner wall of the reflector cup bracket is arranged with a step, and a surface of the color conversion layer facing the second adhesive layer abuts against the step. By setting the step, the flat mounting of the color conversion layer can be realized, and light without color change can also be prevented from leaking out.
3. In the present disclosure, the LED package of the present disclosure further includes an optical structure, and the optical structure is arranged on a surface of the first adhesive layer away from the color conversion layer. By arranging the optical structure on the first adhesive layer, the light emitted angle is increased, and the light emitted efficiency is improved.
4. In the present disclosure, a light reflecting layer or a light shielding layer is arranged in a middle region of a surface of the first adhesive layer away from the color conversion layer, thereby effectively reducing the light emitted from a top center of the LED chip after the packaging, and increasing the light emitting angle and making the emitted light more uniform.
5. In the present disclosure, the third adhesive layer covers the first adhesive layer and protrudes in a direction away from the first adhesive layer. Therefore, a protruding section of the third adhesive layer forms a curved surface structure to further increase the light emitting angle.
6. In the present disclosure, a lens layer is arranged in the middle region of the surface of the first adhesive layer away from the color conversion layer, thereby reducing the light emitted from the top center of the LED chip after the packaging, and increasing the light emitting angle.
7. In the present disclosure, thicknesses of the first adhesive layer and the second adhesive layer are greater than 0 mm and less than or equal to 10 mm. By controlling the thicknesses of the first adhesive layer and the second adhesive layer, the LED package and the LED chip can be effectively packaged, and the effectiveness of the packaging can be improved.
8. In the present disclosure, a distance between a recessed vertex of the recessed space and a bottom surface of the housing space is greater than 0 mm and less than or equal to 5 mm. By setting the distance between the recessed vertex and the bottom surface of the housing space, sufficient recessed space can be reserved to accommodate the LED chip and perform final packaging.
9. In the present disclosure, an LED lamp bead is further provided, which has the same beneficial effects as the above-mentioned LED package, and will not be described again here.

### BRIEF DESCRIPTION OF THE DRAWINGS

To explain the technical solutions of embodiments in the present disclosure more clearly, the accompanying drawings required in the description of the embodiments or the related art are introduced briefly below. Obviously, the drawings in the following description are only some embodiments of the present disclosure, and other drawings can be obtained according to these drawings without creative efforts for those ordinary skilled in the art.

FIG. 1 is a cross-sectional view of an LED package provided by a first embodiment of the present disclosure.

FIG. 2 is a cross-sectional view of a reflector cup bracket of the LED package provided by a first embodiment of the present disclosure.

FIG. 3 is a cross-sectional view of a first implementation of the LED package provided by a first embodiment of the present disclosure.

FIG. 4 is a cross-sectional view of a second implementation of the LED package provided by a first embodiment of the present disclosure.

FIG. 5 is a cross-sectional view of an optical structure of the LED package provided by a first embodiment of the present disclosure.

FIG. 6 is a cross-sectional view of a light reflecting layer of the LED package provided by a first embodiment of the present disclosure.

FIG. 7 is a cross-sectional view of a light shielding layer of the LED package provided by a first embodiment of the present disclosure.

FIG. 8 is a cross-sectional view of a curved surface of a third adhesive layer of the LED package provided by a first embodiment of the present disclosure.

FIG. 9 is a cross-sectional view of a concave curved surface of the third adhesive layer of the LED package provided by a first embodiment of the present disclosure.

FIG. 10 is a cross-sectional view of a first example of a lens layer of the LED package provided by a first embodiment of the present disclosure.

FIG. 11 is a cross-sectional view of a second example of the lens layer of the LED package provided by a first embodiment of the present disclosure.

FIG. 12 is a cross-sectional view of an LED lamp bead provided by a second embodiment of the present disclosure.

FIG. 13 is a cross-sectional view of another implementation of the LED lamp bead provided by a second embodiment of the present disclosure.

Reference numerals and denotations thereof:
1—LED package; and 2—LED lamp bead;
11—reflector cup bracket; 12—first adhesive layer; 13—second adhesive layer; 14—color conversion layer; 15—optical structure; 16—main adhesive layer; 21—substrate; 22—LED chip; and 23—packaging adhesive layer;
111—housing space; 112—inner wall; 131—recessed space; and 141—accommodating space;
151—light reflecting layer; 152—light shielding layer; 153—third adhesive layer; and 154—lens layer; and
1111—light-emitting surface; 1112—bottom surface; 1121—step; 1311—recessed vertex; 1531—recessed center; 1541—first lens structure; and 1542—second lens structure.

### DETAILED DESCRIPTION

For clearer objectives, technical solutions and advantages of the present disclosure, the present disclosure will be further described in detail below with reference to the accompanying drawings and exemplary examples. It is to be understood that the specific embodiments described herein are only used to explain the present disclosure and are not intended to limit the present disclosure.

It is to be noted that when an element is referred to as being “fixed to” another element, it can be directly on the other element or there may also be intervening elements. When an element is referred to as being “connected” to another element, it can be directly connected to the other element or there may also be intervening elements present simultaneously. The terms “vertical”, “horizontal”, “left”, “right” and similar expressions are used herein for illustrative objectives only.

In the present disclosure, the terms “upper”, “lower”, “left”, “right”, “front”, “rear”, “top” “bottom”, “inner”, “outer”, “middle”, “vertical”, “horizontal”, “transverse”, “longitudinal”, and the like designate orientations or positional relationships based on the orientation or positional relationships shown in the drawings. These terms are primarily used to better describe the present disclosure and embodiments thereof, and are not intended to limit the indicated device, element or component to a particular orientation, or to be constructed and operated in a particular orientation.

Moreover, in addition to indicating orientation or positional relationships, some of the above terms may also be used to indicate other meanings. For example, the term “upper” or “on” may also be used to indicate a certain attachment relationship or connection relationship in some cases. For those ordinary skilled in the art, the specific meanings of these terms in the present disclosure can be understood on specific circumstances.

Furthermore, the terms “mounted”, “arranged”, “provided”, “communication”, and “connected” are to be understood broadly. For example, a connection can be a fixed connection, a detachable connection, or a unitary construction; a mechanical connection, or an electrical connection; a direct connection, an indirect connection through an intermediate medium; or internal communication between two devices, elements, or components. For those ordinary skilled in the art, the specific meanings of the above terms in the present disclosure can be understood according to specific circumstances.

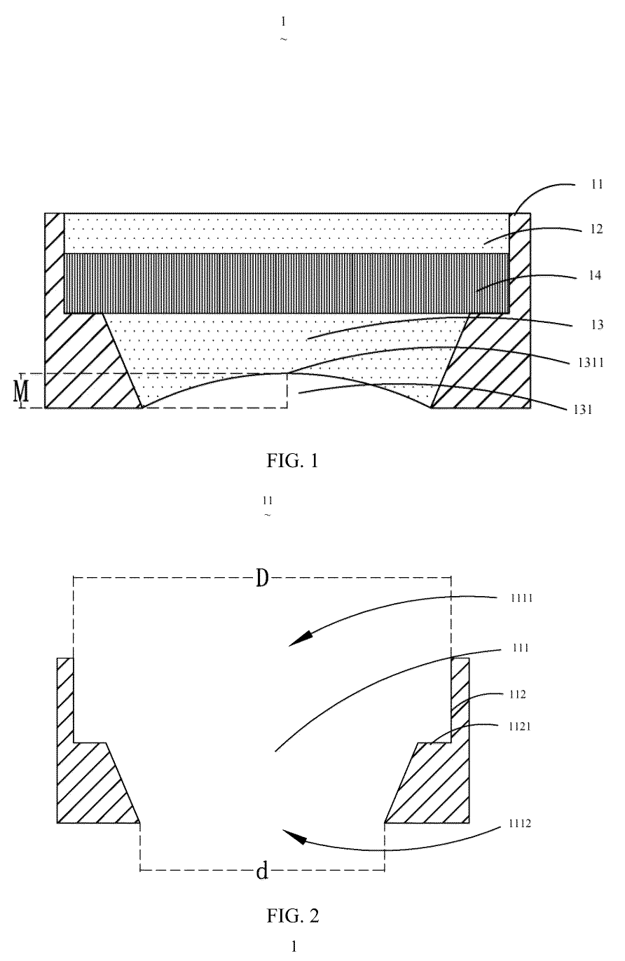

Referring to FIG. 1 and FIG. 2, a first embodiment of the present disclosure provides an LED package 1, including a reflector cup bracket 11 hollow to form a housing space 111. A first adhesive layer 12, a second adhesive layer 13, and a color conversion layer 14 arranged between the first adhesive layer 12 and the second adhesive layer 13 are arranged in the housing space 111, and a surface of the second adhesive layer 13 away from the color conversion layer 14 is recessed toward the color conversion layer 14 to form a recessed space 131.

Specifically, the reflector cup bracket 11 has a reflector cup shape, and the housing space 111 formed by hollow inside also has a reflector cup shape as a whole. The housing space 111 includes a bottom surface 1112 and a light-emitting surface 1111. A width D (D as shown in FIG. 2) of the light-emitting surface 1111 is greater than a width d (d as shown in FIG. 2) of the bottom surface 1112. When the width D of the light-emitting surface 1111 is greater than the width d of the bottom surface 1112, after the LED package 1 and the LED chip are packaged, an optimal light-emitting effect can be achieved. Specifically, the reflector cup structure can concentrate light directly above the LED chip, making the center brightness higher and the overall brightness higher. In addition, the reflector cup structure is also more suitable for lens matching and reducing the generation of halos.

It is to be understood that the first adhesive layer 12, the color conversion layer 14 and the second adhesive layer 13 are arranged in sequence in the housing space 111 along a direction from the light-emitting surface 1111 to the bottom surface 1112 to form a hierarchical structure, that is, the color conversion layer 14 is located between the first adhesive layer 12 and the second adhesive layer 13, thereby separating the first adhesive layer 12 and the second adhesive layer 13. A surface of the second adhesive layer 13 away from the color conversion layer 14 is recessed in a direction toward the color conversion layer 14 to form the recessed space 131. The recessed space 131 is opposite to the bottom surface 1112 of the housing space 111. The recessed space 131 is specifically a space reserved for bonding a substrate 21 and the LED chip. The recessed space 131 can specifically be a curved surface structure, which better matches the state of the LED chip when it emits light. In this way, by arranging the first adhesive layer 12, the second adhesive layer 13 and the color conversion layer 14 in the housing space 111 of the reflector cup bracket 11, the LED package 1 independent of the LED chip can be formed, and the arranged recessed space 131 is a reserved space for placing the LED chip. Therefore, when the LED package 1 and the LED chip are packaged, the color conversion layer 14 can be directly used for cutting, and the LED package 1 can be directly attached above the LED chip for color conversion, which not only ensures the color consistency of the device, but also avoids the failure of a film material contacting with water vapor, thereby saving the cost of the entire film material, and further greatly reducing the cost of color conversion.

Further, thicknesses of the first adhesive layer 12 and the second adhesive layer 13 are greater than 0 mm and less than or equal to 10 mm.

It is to be understood that by controlling the thicknesses of the first adhesive layer 12 and the second adhesive layer 13, the first adhesive layer 12, the second adhesive layer 13 and the reflector cup bracket 11 can be effectively and firmly bonded, the LED package 1 and the LED chip can be effectively packaged, and finally the effectiveness of the packaging can be improved. In this embodiment, preferably, the thicknesses of the first adhesive layer 12 and the second adhesive layer 13 may be 0.1 mm. By using the first adhesive layer 12 and the second adhesive layer 13 with this thickness, the LED chip can be packaged while effectively adhering to the reflector cup bracket 11.

Alternatively, materials of the first adhesive layer 12 and the second adhesive layer 13 are not limited in this embodiment, as long as the materials are transparent and have an adhesive effect. Preferably, the first adhesive layer 12 and the second adhesive layer 13 may be transparent silica gel layers. The first adhesive layer 12 and the second adhesive layer 13 using a common packaging adhesive system such as silica gel and epoxy have high adhesive performance, are more firmly adhered to the reflector cup bracket 11, have good light transmittance, and light emitted by the LED chip can be fully transmitted and scattered, thereby improving the brightness and uniformity of the light.

Alternatively, the color conversion layer 14 is made of a color conversion material. The color conversion material is not limited, as long as the LED chip can be color-converted. In this embodiment, preferably, the color conversion layer 14 may specifically be a color conversion film, the LED chip may be an LED blue light chip, and white light can be formed after packaging.

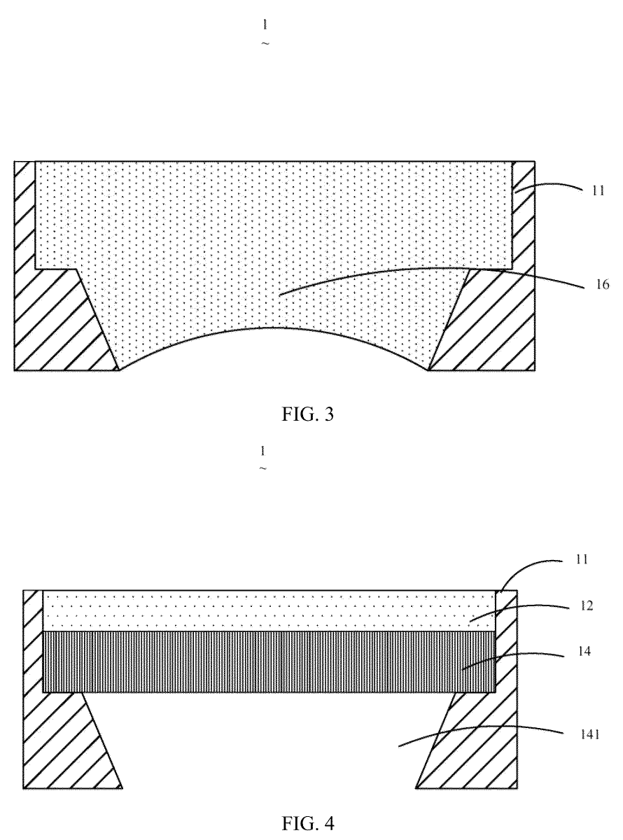

Referring to FIG. 3, as an alternative first implementation, the housing space 111 may not include the color conversion layer 14, and only includes an integral main adhesive layer 16 included by the first adhesive layer 12 and the second adhesive layer 13. A thickness of the main adhesive layer 16 is greater than 0 mm and less than or equal to 20 mm. Therefore, through the reflector cup bracket 11 and the main adhesive layer 16, after the LED package 1 without the color conversion layer 14 is packaged with the LED chip, light is gathered directly above the LED chip, making the center brightness higher and the overall brightness higher. That is, the LED package 1 without the color conversion layer 14 is only used as an implementation for improving brightness.

Referring to FIG. 4, as another alternative second implementation, the housing space 111 may not include the second adhesive layer 13, and only includes the first adhesive layer 12 and the color conversion layer 14. An accommodating space 141 for accommodating other optical products is formed between the color conversion layer 14 and the reflector cup bracket 11. In the accommodating space 141, adhesive may be directly dispensed on the LED chip and bonded to a bottom of the reflector cup bracket 11, and the entire LED chip is covered by the accommodating space 141. The LED package 1 in this implementation can adapt to the reliability requirements lower than the reliability requirements of optical products that use blue COB color conversion to form white light, thereby increasing the versatility of the prepared LED package 1.

Referring to FIG. 1, further, a distance M (M as shown in FIG. 1) between a recessed vertex 1311 of the recessed space 131 and the bottom surface 1112 of the housing space 111 is greater than 0 mm and less than or equal to 5 mm.

Specifically, a surface of the second adhesive layer 13 away from the color conversion layer 14, that is, a surface forming the recessed space 131, specifically has a curved surface structure. The curved surface has a curved surface vertex. A distance between the curved surface vertex and a surface of the second adhesive layer 13 close to the color conversion layer 14 is the closest, and a distance between the curved surface vertex and the bottom surface 1112 of the housing space 111 is the farthest. The curved surface vertex is also the recessed vertex 1311 of the recessed space 131.

It is to be understood that by arranging the distance M between the recessed vertex 1311 of the recessed space 131 and the bottom surface 1112 of the housing space 111 to be greater than 0 mm and less than or equal to 5 mm, a height range of the recessed space 131 can be controlled, and a size of the recessed space 131 can be limited by controlling the height. Therefore, by appropriately arranging the distance M between the recessed vertex 1311 of the recessed space 131 and the bottom surface 1112 of the housing space 111, a large enough recessed space 131 can be reserved to accommodate the LED chip for final packaging. In this embodiment, preferably, a distance between the recessed vertex 1311 of the recessed space 131 and the packaged LED chip can be set to 0.4 mm, and setting 0.4 mm makes it easier for an adhesive layer on the LED chip and the second adhesive layer 13 to be pressed together to fill the entire recessed space 131.

Referring to FIG. 2, further, an inner wall 112 of the reflector cup bracket 11 is arranged with a step 1121, and a surface of the color conversion layer 14 facing the second adhesive layer 13 is abutted against the step 1121.

It is to be understood that the step 1121 may be arranged on the inner wall 112 of the reflector cup bracket 11, and the step 1121 may be an integral annular step 1121, or may be a plurality of steps 1121 distributed at intervals and in parallel, which is not limited in this embodiment, as long as the surface of the color conversion layer 14 facing the second adhesive layer 13 can abut against and fit snugly the step 1121, that is, a shape of the step 1121 matches a boundary of the color conversion layer 14, thereby supporting the step 1121 and realizing the flat mounting of the color conversion layer 14. In addition, by arranging the step 1121, light without color change can also be prevented from leaking out, thereby avoiding affecting the emission of white light.

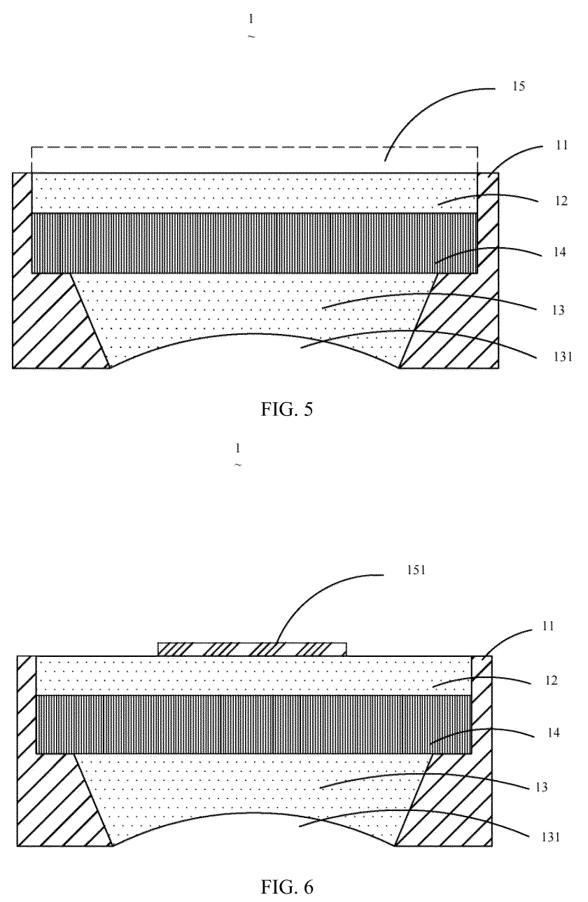

Referring to FIG. 5, further, the LED package 1 further includes an optical structure 15, and the optical structure 15 is arranged on a surface of the first adhesive layer 12 away from the color conversion layer 14.

It is to be understood that to increase the light emitting angle and improve the light emitting efficiency, the optical structure 15 is arranged on the surface of the first adhesive layer 12 away from the color conversion layer 14. By arranging the optical structure 15, the light emitting angle can be increased and the light emitting efficiency can be improved.

Referring to FIGS. 5-10, further, the optical structure 15 is one of a light reflecting layer 151, a light shielding layer 152, a third adhesive layer 153 and a lens layer 154.

It is to be understood that the optical structure 15 may be any one of the light reflecting layer 151, the light shielding layer 152, the third adhesive layer 153 and the lens layer 154. By arranging the light reflecting layer 151 or the light shielding layer 152 or the third adhesive layer 153 or the lens layer 154 on the surface of the first adhesive layer 12 away from the color conversion layer 14, the light emitting angle can be increased, and the light emitting efficiency can be improved.

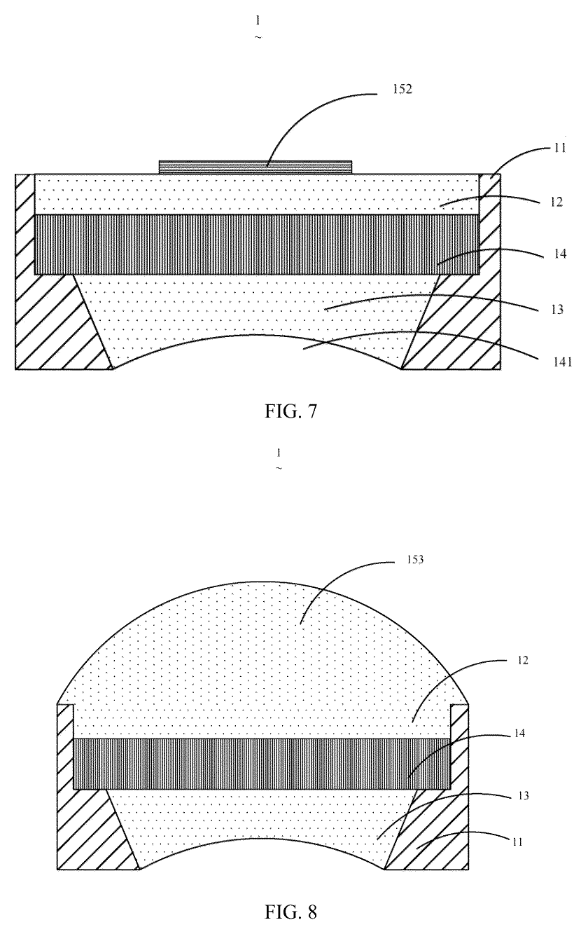

Referring to FIG. 6 and FIG. 7, further, the light reflecting layer 151 or the light shielding layer 152 is arranged in a middle region of the surface of the first adhesive layer 12 away from the color conversion layer 14.

It is to be understood that the light reflecting layer 151 and the light shielding layer 152 are arranged at the same position, and are arranged in a middle region of the surface of the first adhesive layer 12 away from the color conversion layer 14. Therefore, after the final packaging of the LED package 1 and the LED chip, the LED chip is located in the middle region of the bottom surface 1112 of the housing space 111, and the middle region is also a region corresponding to a middle region of the recessed space 131. Therefore, the LED chip is located opposite to the light reflecting layer 151 or the light shielding layer 152, thereby effectively reducing the light emitted from a top center of the LED chip after the packaging, and increasing the light emitting angle and making the emitted light more uniform.

Specifically, as an alternative implementation. Referring to FIG. 6, in FIG. 6, the surface of the first adhesive layer 12 away from the color conversion layer 14 is the light reflecting layer 151. After the LED package 1 and the LED chip are finally packaged, the light reflecting layer 151 reflects the light emitted from the top center of the LED chip, thereby effectively reducing the light emitted from the top center of the LED chip after the packaging, and realizing large-angle light emission of the LED chip on the light-emitting surface 1111 of the reflector cup bracket 11.

As another alternative implementation, referring to FIG. 7, in FIG. 7, the light shielding layer 152 is arranged on the surface of the first adhesive layer 12 away from the color conversion layer 14. After the LED package 1 and the LED chip are finally packaged, the light shielding layer 152 shields the light emitted from the top center of the LED chip, thereby effectively reducing the light emitted from the top center of the LED chip after the packaging, and realizing large-angle light emission of the LED chip on the light-emitting surface 1111 of the reflector cup bracket 11.

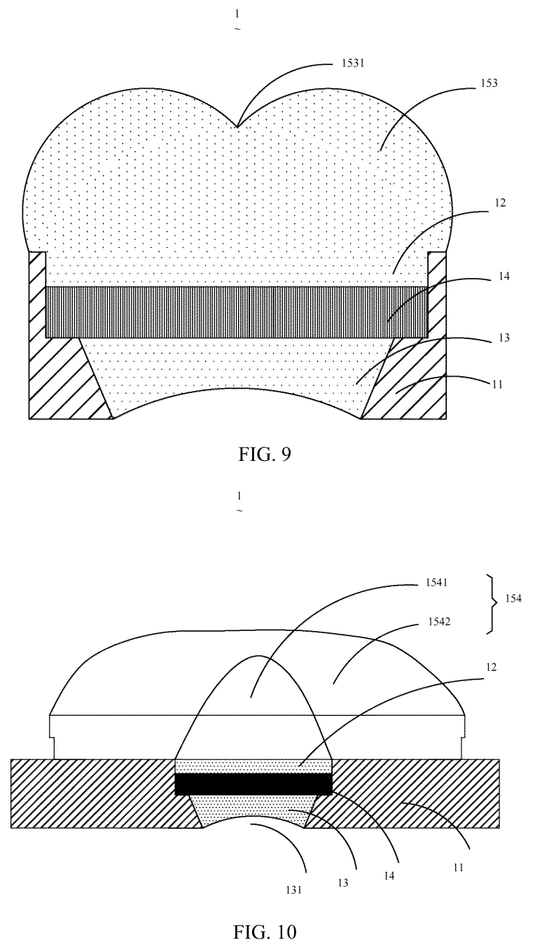

Referring to FIG. 8 and FIG. 9, further, as another alternative implementation, the third adhesive layer 153 is arranged on the surface of the first adhesive layer 12 away from the color conversion layer 14. The third adhesive layer 153 covers the first adhesive layer 12 and protrudes in a direction away from the first adhesive layer 12.

Specifically, the third adhesive layer 153 needs to cover the surface of the first adhesive layer 12 away from the color conversion layer 14, and cover a boundary of the reflector cup bracket 11; and the third adhesive layer 153 completely covers light emitted from the LED chip 22 through the first adhesive layer 12 to avoid omission. Moreover, the third adhesive layer 153 needs to protrude in the direction away from the first adhesive layer 12, that is, a surface of the third adhesive layer 153 away from the first adhesive layer 12 needs to be curved, and the curved third adhesive layer 153 enlarges the angle and area of light emitted from the LED chip through the first adhesive layer 12.

It is to be noted that, the third adhesive layer 153 may be formed on the first adhesive layer 12 by means of dispensing, and specifically, the third adhesive layer 153 may be formed by means of dispensing, by means of common dispensing or optical dispensing, on the surface of the first adhesive layer 12 away from the color conversion layer 14. The dispensing manner of the third adhesive layer 153 is not limited in this embodiment, as long as the third adhesive layer 153 covers the first adhesive layer 12 and protrudes in the direction away from the first adhesive layer 12.

Referring to FIG. 8, alternatively, a protruding surface shape of the third adhesive layer 153 can be an overall curved surface, and the light emitted from the LED chip through the first adhesive layer 12 can be more uniformly emitted after passing through the third adhesive layer 153.

Referring to FIG. 9, alternatively, a convex shape of the third adhesive layer 153 may be a concave curved surface. A recessed center 1531 of the concave curved surface corresponds to a center of the surface of the first adhesive layer 12 away from the color conversion layer 14, and that is, a center directly opposite to the packaged LED chip. By arranging the recessed center 1531, when the light emitted from the top center of the LED chip passes through the recessed center 1531, the light is emitted from a curved surface beside the recessed center 1531, rather than directly emitted from the recessed center 1531, thereby reducing the direct light emitted from the top center of the LED chip 22 after the packaging, which is beneficial to increase the overall light emitting angle.

Referring to FIG. 10 and FIG. 11, further, as another alternative implementation, the lens layer 154 is arranged in the middle region of the surface of the first adhesive layer 12 away from the color conversion layer 14.

Specifically, the lens layer 154 includes an inner first lens structure 1541 and an outer second lens structure 1542 wrapping the first lens structure 1541. The first lens structure 1541 is arranged in the middle region of the surface of the first adhesive layer 12 away from the color conversion layer 14, the second lens structure 1542 wraps the first lens structure 1541, and the first lens structure 1541 is located at a central position of the second lens structure 1542. Therefore, after the LED package 1 is used to package the LED chip, a position of the first lens structure 1541 corresponds to a position of the LED chip on the bottom surface 1112 of the housing space 111. The correspondence is vertical opposition. The light emitted from the top center of the LED chip can first be refracted through the first lens structure 1541, and the refracted light is emitted through the mask-type second lens structure 1542. Therefore, through the refraction of an inner condenser lens of the first lens structure 1541 and the mask-type second lens structure 1542, the light emitted from the top center of the LED chip is turned on, thereby realizing the control of the light emitted from the top center of the LED chip. The light emitting angle of the top center of the LED chip is enlarged, the direct light emitted from the top center of the LED chip after the packaging is reduced, and the overall light emitting angle is increased.

It is to be noted that a size of the lens layer 154 is not limited in this embodiment, and may be greater than a size of a surface of the reflector cup bracket 11 away from the recessed space 131, or may be less than or equal to the size of the surface of the reflector cup bracket 11 away from the recessed space 131, as long as the lens layer 154 can correspond to a position of the packaged LED chip, and that is, the lens layer 154 is arranged along the middle region of the surface of the first adhesive layer 12 away from the color conversion layer 14. In this embodiment, preferably, a size of the lens layer 154 needs to satisfy that the lens layer 154 is arranged in the middle region of the surface of the first adhesive layer 12 away from the color conversion layer 14 and covers the surface of the first adhesive layer 12 away from the color conversion layer 14, thereby avoiding missing light emitted from the top center of the LED chip after the packaging, and expanding the light emitted angle from the top center of the LED chip to the maximum extent. Specifically, referring to FIG. 10 and FIG. 11, FIG. 10 is a first example diagram showing that the size of the lens layer 154 is less than the size of the surface of the reflector cup bracket 11 away from the recessed space 131. FIG. 11 is a second example diagram showing that the size of the lens layer 154 is greater than the size of the surface of the reflector cup bracket 11 away from the recessed space 131.

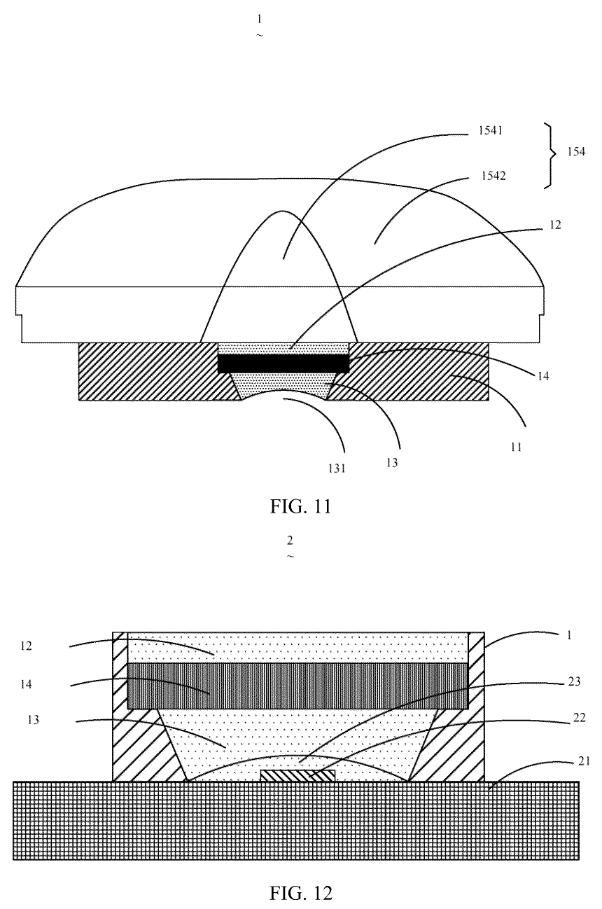

Referring to FIG. 12, a second embodiment of the present disclosure provides an LED lamp bead 2. The LED lamp bead 2 includes the substrate 21, the LED chip 22 arranged on the substrate 21, and the LED package 1 according to any one of the second embodiments. A packaging adhesive layer 23 is arranged on the LED chip 22, the LED chip 22 is located in the recessed space 131, and the packaging adhesive layer 23 is connected to the second adhesive layer 13.

It is to be understood that, since the LED package 1 in the first embodiment is an independent LED package 1 relative to the LED chip 22, when the LED package 1 is packaged with the LED chip 22, the color conversion layer 14 can be directly used for cutting, and the LED package 1 can be directly attached above the LED chip 22 for color conversion, which not only ensures the color consistency of the device, but also avoids the failure of a film material contacting with water vapor, thereby saving the cost of the entire film material, and further greatly reducing the cost. In addition, the overall reflector cup structure presented by the LED package 1 can concentrate light directly above the LED chip 22, making the center brightness higher and the overall brightness higher. In addition, the reflector cup structure is also more suitable for lens matching and reducing the generation of halos.

The specific packaging process is as follows. Firstly, the LED chip 22 is placed on the substrate 21; glue is applied to the LED to form the packaging glue layer 23; and the LED package 1 is covered directly above the LED chip 22 with the packaging adhesive layer 23 and pressed downward, the packaging adhesive layer 23 and the second adhesive layer 13 reach a state of complete contact, baking and curing are performed, and the packaging adhesive layer 23 and the second adhesive layer 13 are bonded to each other at contact surfaces thereof, thereby completing the packaging.

Alternatively, a material of the packaging adhesive layer 23 is not limited in this embodiment, and may be the same as the materials of the first adhesive layer 12 and the second adhesive layer 13, as long as the material is transparent and has an adhesive effect. Preferably, the packaging adhesive layer 23 may be a transparent silica gel layer. The packaging adhesive layer 23 using a common packaging adhesive system such as silica gel and epoxy has high adhesive performance, and is more firmly adhered to the LED chip 22 and the second adhesive layer 13. Meanwhile, the packaging adhesive layer 23 has good light transmittance, and the light emitted by the LED chip 22 can be fully transmitted and scattered, thereby improving the brightness and uniformity of the light.

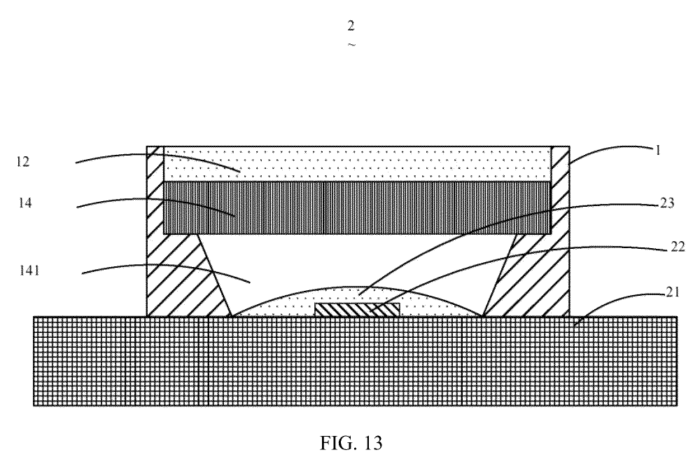

Referring to FIG. 13, as an alternative implementation, the LED package 1 may not include the second adhesive layer 13, the LED chip 22 is located in the accommodating space 141 formed by the color conversion layer 14 and the reflector cup bracket 11, and the entire LED chip is covered by the accommodating space 141. The LED package 1 in this implementation can adapt to the reliability requirements lower than the reliability requirements of optical products that use blue COB color conversion to form white light, thereby increasing the versatility of the prepared LED package 1.

Compared with the related art, the LED package and the LED lamp bead of the present disclosure have the following advantages.
1. In the present disclosure, the LED package is provided, including a reflector cup bracket hollow to form a housing space. A first adhesive layer, a second adhesive layer, and a color conversion layer arranged between the first adhesive layer and the second adhesive layer are arranged in the housing space, and a surface of the second adhesive layer away from the color conversion layer is recessed toward the color conversion layer to form a recessed space. By arranging the first adhesive layer, the second adhesive layer and the color conversion layer in the housing space of the reflector cup bracket, the LED package independent of the LED chip can be formed, and the arranged recessed space is a reserved space for placing the LED chip. Therefore, when the LED package and the LED chip are packaged, the color conversion layer can be directly used for cutting, and the LED package can be directly attached above the LED chip for color conversion, which not only ensures the color consistency of the device, but also avoids the failure of a film material contacting with water vapor, thereby saving the cost of the entire film material, and further greatly reducing the cost of color conversion.
2. In the present disclosure, an inner wall of the reflector cup bracket is arranged with a step, and a surface of the color conversion layer facing the second adhesive layer abuts against the step. By setting the step, the flat mounting of the color conversion layer can be realized, and light without color change can also be prevented from leaking out.
3. In the present disclosure, the LED package of the present disclosure further includes an optical structure, and the optical structure is arranged on a surface of the first adhesive layer away from the color conversion layer. By arranging the optical structure on the first adhesive layer, the light emitted angle is increased, and the light emitted efficiency is improved.
4. In the present disclosure, a light reflecting layer or a light shielding layer is arranged in a middle region of a surface of the first adhesive layer away from the color conversion layer, thereby effectively reducing the light emitted from a top center of the LED chip after the packaging, and increasing the light emitting angle and making the emitted light more uniform.
5. In the present disclosure, the third adhesive layer covers the first adhesive layer and protrudes in a direction away from the first adhesive layer. Therefore, a protruding section of the third adhesive layer forms a curved surface structure to further increase the light emitting angle.
6. In the present disclosure, a lens layer is arranged in the middle region of the surface of the first adhesive layer away from the color conversion layer, thereby reducing the light emitted from the top center of the LED chip after the packaging, and increasing the light emitting angle.
7. In the present disclosure, thicknesses of the first adhesive layer and the second adhesive layer are greater than 0 mm and less than or equal to 10 mm. By controlling the thicknesses of the first adhesive layer and the second adhesive layer, the LED package and the LED chip can be effectively packaged, and the effectiveness of the packaging can be improved.
8. In the present disclosure, a distance between a recessed vertex of the recessed space and a bottom surface of the housing space is greater than 0 mm and less than or equal to 5 mm. By setting the distance between the recessed vertex and the bottom surface of the housing space, sufficient recessed space can be reserved to accommodate the LED chip and perform final packaging.
9. In the present disclosure, an LED lamp bead is further provided, which has the same beneficial effects as the above-mentioned LED package, and will not be described again here.

The above description is merely a preferred embodiment of the present disclosure and is not intended to limit the present disclosure. Any modifications, equivalent replacements and improvements made within the principles of the present disclosure shall be included within the protection scope of the present disclosure.

1. A light emitting diode (LED) package, comprising a reflector cup bracket hollow to form a housing space, wherein a first adhesive layer, a second adhesive layer, and a color conversion layer arranged between the first adhesive layer and the second adhesive layer are arranged in the housing space, and a surface of the second adhesive layer away from the color conversion layer is recessed toward the color conversion layer to form a recessed space.

2. The LED package according to claim 1, wherein an inner wall of the reflector cup bracket is arranged with a step, and a surface of the color conversion layer facing the second adhesive layer is abutted against the step.

3. The LED package according to claim 1, wherein the LED package further comprises an optical structure, and the optical structure is arranged on a surface of the first adhesive layer away from the color conversion layer.

4. The LED package according to claim 3, wherein the optical structure is one of a light reflecting layer, a light shielding layer, a third adhesive layer and a lens layer.

5. The LED package according to claim 4, wherein the light reflecting layer or the light shielding layer is arranged in a middle region of a surface of the first adhesive layer away from the color conversion layer.

6. The LED package according to claim 4, wherein the third adhesive layer covers the first adhesive layer and protrudes in a direction away from the first adhesive layer.

7. The LED package according to claim 4, wherein the lens layer is arranged in the middle region of the surface of the first adhesive layer away from the color conversion layer.

8. The LED package according to claim 1, thicknesses of the first adhesive layer and the second adhesive layer are greater than 0 mm and less than or equal to 10 mm.

9. The LED package according to claim 1, a distance between a recessed vertex of the recessed space and a bottom surface of the housing space is greater than 0 mm and less than or equal to 5 mm.

10. An LED lamp bead, comprising a substrate, an LED chip arranged on the substrate, and the LED package according to claim 1, wherein a packaging adhesive layer is arranged on the LED chip, the LED chip is located in the recessed space, and the packaging adhesive layer is connected to the second adhesive layer.

11. An LED lamp bead, comprising a substrate, an LED chip arranged on the substrate, and the LED package according to claim 2, wherein a packaging adhesive layer is arranged on the LED chip, the LED chip is located in the recessed space, and the packaging adhesive layer is connected to the second adhesive layer.

12. An LED lamp bead, comprising a substrate, an LED chip arranged on the substrate, and the LED package according to claim 3, wherein a packaging adhesive layer is arranged on the LED chip, the LED chip is located in the recessed space, and the packaging adhesive layer is connected to the second adhesive layer.

13. An LED lamp bead, comprising a substrate, an LED chip arranged on the substrate, and the LED package according to claim 4, wherein a packaging adhesive layer is arranged on the LED chip, the LED chip is located in the recessed space, and the packaging adhesive layer is connected to the second adhesive layer.

14. An LED lamp bead, comprising a substrate, an LED chip arranged on the substrate, and the LED package according to claim 5, wherein a packaging adhesive layer is arranged on the LED chip, the LED chip is located in the recessed space, and the packaging adhesive layer is connected to the second adhesive layer.

15. An LED lamp bead, comprising a substrate, an LED chip arranged on the substrate, and the LED package according to claim 6, wherein a packaging adhesive layer is arranged on the LED chip, the LED chip is located in the recessed space, and the packaging adhesive layer is connected to the second adhesive layer.

16. An LED lamp bead, comprising a substrate, an LED chip arranged on the substrate, and the LED package according to claim 7, wherein a packaging adhesive layer is arranged on the LED chip, the LED chip is located in the recessed space, and the packaging adhesive layer is connected to the second adhesive layer.

17. An LED lamp bead, comprising a substrate, an LED chip arranged on the substrate, and the LED package according to claim 8, wherein a packaging adhesive layer is arranged on the LED chip, the LED chip is located in the recessed space, and the packaging adhesive layer is connected to the second adhesive layer.

18. An LED lamp bead, comprising a substrate, an LED chip arranged on the substrate, and the LED package according to claim 9, wherein a packaging adhesive layer is arranged on the LED chip, the LED chip is located in the recessed space, and the packaging adhesive layer is connected to the second adhesive layer.
